(19) United States
(12) Patent Application Publication
(10) Pub. No.: US 2026/0322235 A1
(43) Pub. Date: Oct. 15, 2026

(54) POWER CONVERTER INTERCONNECTION

(71) Applicant: The Regents of the University of Michigan, Ann Arbor, MI (US)

(72) Inventors: Al-Thaddeus Avestruz, Ann Arbor, MI (US); Xiaofan Cui, Sherman Oaks, CA (US); Alireza Ramyar, Ann Arbor, MI (US); Wentao Xu, Ann Arbor, MI (US); Jason Siegel, Ann Arbor, MI (US); Anna Stefanopoulou, Ann Arbor, MI (US)

(21) Appl. No.: 19/117,289

(22) PCT Filed: Oct. 2, 2023
(86) PCT No.: PCT/US2023/075703

§ 371 Date: Mar. 31, 2025

Related U.S. Application Data
(60) Provisional application No. 63/412,117, filed on Sep. 30, 2022.

(51) Int. Cl. H02M 1/00; G01R 31/392; H02J 3/32; H02J 3/38; H02J 3/46; H02J 7/34; H02J 103/30

(52) U.S. Cl. CPC H02M 1/0012; G01R 31/392; H02J 3/32; H02J 3/381; H02J 3/46; H02J 7/34; H02M 1/007; H02J 2103/30

(57) ABSTRACT

A power conversion device may perform mod-el-referenced power processing for multiple power nodes connected at one or more power ports. The power conversion device may include binning logic to bin the occupied ports according to their estimated condition of the occupying nodes within a pre-defined condition model for an expected population of power nodes. The binning logic then interconnects the binned ports to lite and sparse layer nodes in accordance with the occupancy and binning.

### BACKGROUND

### Priority

This application claims priority to U.S. Provisional Application No. 63/412,117 filed Sep. 30, 2022, bearing Attorney Docket No. 10109-22017P, and titled POWER CONVERTER INTERCONNECTION, which is incorporated by reference herein in its entirety.

### STATEMENT REGARDING FEDERALLY SPONSORED RESEARCH OR DEVELOPMENT

This invention was made with government support under Contract No. 2146490 awarded by the National Science Foundation. The government has certain rights in the invention.

### Technical Field

The disclosure relates generally to power converter interconnection.

### BRIEF DESCRIPTION OF RELATED TECHNOLOGY

Increasingly complex electronics have given rise to need for power conversion and other signal processing in various contexts. For example, devices including power supply circuitry may power components at various power levels and/or other input constraints. Accordingly, there is increasing demand for systems that efficiently and accurately process signals in variety of power and frequency environments. Improvements to signal processing technologies will continue to drive industrial demand.

### BRIEF DESCRIPTION OF THE DRAWINGS

FIG. 1 shows an example power conversion device.

FIG. 2 shows example binning logic.

FIG. 3 shows an example binning execution system.

### DETAILED DESCRIPTION

In various contexts, a power source, such as a power store (e.g., a battery, fuel cell, or other power store), solar cell, wind turbine, chemical process, or other power source, may output power in a state (e.g., voltage, wattage, current, direct current, alternating current, or other characterization metric) that does not match a target output for a system incorporating the power source. Various contexts may have mismatch between multiple power sinks connected in a unified system (e.g., battery chargers, motors, or other power consuming devices). In other words, a system may have heterogeneity resulting from various power nodes (e.g., power sources and/or power sinks) in the system.

Using batteries as an illustrative example, batteries that may be uniform or otherwise non-diverse (e.g., at the time of manufacture, installation, or other life cycle point) may degrade at different rates, in some cases, including contexts of uniform and/or load balanced usage. Thus, an initially uniform set of batteries may degrade such that the output of the example set differs from the target output of the system. Further, the deviation from the target (or the expected contribution to the target) output by individual batteries in the example set may differ from battery to battery. Diverse degradation may occur at various levels of battery technology, for example different battery packs may degrade differently, further within those packs modules and/or individual cells may have diverse degradation. Batteries may refer to any portion of battery technologies and/or other technologies that behavior as a power storage unit. For example, multiple battery packs, modules, cells, chargers, controllers, power converters, or other battery internals connected via virtually any set of electrical interconnects may, in some cases, be referred to as a single “battery”. Further, power stores (such as batteries) may in various contexts behave as power sources, power sinks (e.g., while charging), or other power nodes. Solar cell/array power generation may differ as a result of transient and/or spatially variant irradiance profiles, cell degradation, cell obfuscation (e.g., via dust or other detritus), or other non-uniform interference with power generation.

As an illustrative scenario, second use of retired electric vehicle (EV) battery packs (e.g., as residential power backup or other power backup) may require installation of battery packs that have already undergone degradation as a result of usage. Further, battery packs span a wide range of capacities, ratings, and form factors for a wide array of vehicles. The diversity may increase as technologies for faster charging and newer battery chemistries emerge. This diversity is not only reflected in the second use packs for energy storage, but also in the charging of different vehicles within a station. However, during these periods of rapid change, markets may in part resist some standardization since improvements in battery performance provide benefits to producers able to incorporate new technologies when advances outweigh the benefits of standardization.

Similar trade-offs exist between standardization and incorporation of new technology with other power nodes.

In various implementations, systems may implement power converters to convert the power from at power node into the state used at the output port. In various implementations, full power processing (FPP) may include placing a power converter between the power node and the target port to convert the power at the power node to that of the target port. In some cases, a converter may be paired to each node in a group tied to a target port. The converter may process all of the power from the node.

In some cases, partial power processing (PPP) may be implemented. Although the number of converters may be dependent (e.g., equal or similar to) the number of power nodes, the PPP converters may process less than all of the power at the nodes. Instead, processing may be focused on a portion of the power to adjust the power from the power nodes to an output state. In some cases, PPP may reduce the overall power processed. In some cases, PPP operations may increase efficiency relative to FPP because PPP (even with otherwise identical converters) does not process the full power of the system. Accordingly, per converter inefficiencies are reduced by the relative size of the portion being processes. For example, a FPP system processing 100% with 5% loss will lose 5% of the power of the system. A PPP configuration with the same converters processing 10% of the power, will lose 0.5%. Other efficiencies such as reduced internal heating may be gained.

For example, differential power processing (DPP) may operate to on the portion of the power that differs from the target state. In some cases, the power nodes may differ only on a given range (e.g., X % to Y %, where Y>X). Accordingly, power converter set, each individually capable of handling the maximum deviation of the range (e.g., Y %), may be sufficient to support power conversion. In some cases, the cost of a power converter may scale with the processing capacity of the converter. Accordingly, systems configured to employ PPP and/or DPP may have cost savings advantages over FPP systems. However, some FPP systems may operate where no information about current operation condition/future operational condition of power node is known. For example, DPP and PPP may have operational tolerance ranges where a particular output may be delivered. If a set of power nodes falls outside the range (or for example degrades to the point it is outside the range after installation), the PPP system may fail.

In some cases, statistical, empirical, and/or theoretical models may provide information of power node condition. For example, a model of battery degradation versus use and/or time may provide a distribution of states for a given second-use battery population. Accordingly, such a model may provide predictive information on a set of batteries drawn from such a population.

For example, a particular population (or other group) of power nodes may be diverse for one or more reasons such as degradation, model type, or other diversity factors. A condition model, including models generated from power node characterizations, statistical models, or other models of power node performance, may be used to provide information on the expected characteristics of a power node selected from that particular population. Further, using the condition model the population can be divided into defined portions (e.g., bins). The defined portions may be statistical portions, such as percentile ranges, individual node assignments, characterization based assignments or other groupings. Once, divided into portions, the portions may be treated specifically, such that electrical coupling to members of that portion may be specific to the characteristics of that power node portion. Thus, systems using diverse power nodes may anticipate power converter sizing requirements. Accordingly, power converters with lower conversion capacity may be used because the uncertainty if the amount of necessary conversion capacity is reduced.

Therefore, a system capable of processing a set of power nodes with conditions estimated by a model may allow comparatively robust performance to blind and/or limited characterization implementations, while not requiring detailed characterization of individual power nodes in the set. Further, a system capable of making model-referenced corrections may allow for more uniform construction of power processing systems rather than relying on highly power-node-set-specific interconnects and power converter units.

Moreover, an initial limited characterization of a set of power nodes may be supplanted later by a more information rich degradation trajectory obtained through extended use and monitoring of the power nodes. For example, for an initial interconnection and binning of the power nodes, a point characterization (e.g., based on data from a point or otherwise comparatively brief moment in time) may be used to initially interconnect the power nodes in the power processing system at the available ports. After a period of use and monitoring of the power nodes in the power processing system (e.g., after a monitoring period), better characterization of the power nodes may be possible because a longer portion of the power nodes degradation trajectory may be determined from the monitoring data. Thus, the power nodes may be reconnected to the available ports based on the more extensive characterization. In some cases, different monitoring periods may be used. For example, the monitoring period may be based on the expected lifetime of a power node. For example, a battery may be expected to degrade over 10 years. Accordingly, the monitoring period may be selected to be a portion of 10 years (e.g., two years) such that a trajectory of degradation may be ascertained.

Additionally or alternatively, the ports of a power processing system may not necessarily have their logic function tied to a particular physical port location. Accordingly, in some implementations, power nodes may be “reconnected” to the ports in a new order without physical moving or disconnecting the power nodes from the system. Rather, a switching system may reconfigure the routing withing the power processing system such that the logical port align with the newly determined interconnection for the power nodes without physical relocation of the power nodes themselves.

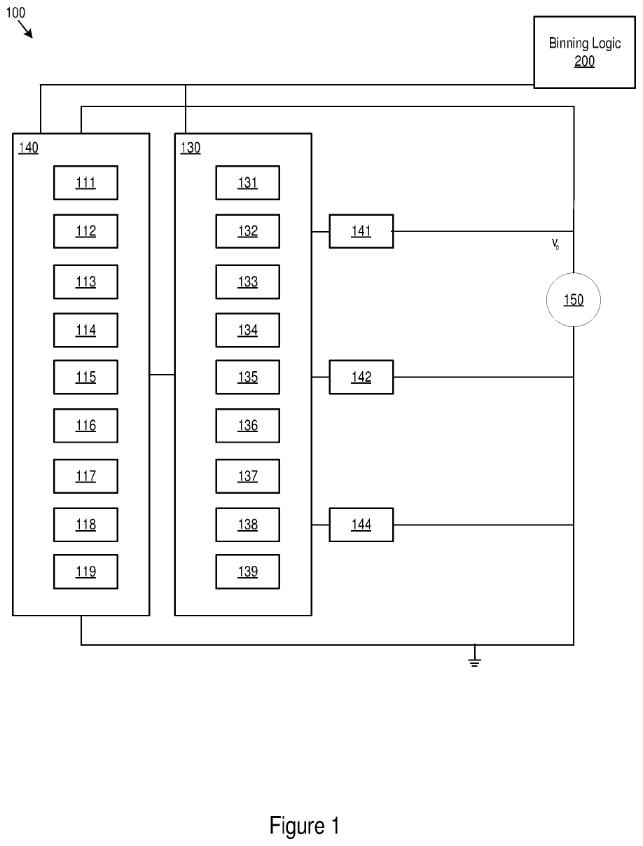

Referring now to FIG. 1, an example power conversion device (PCD) 100 is shown. The example PCD 100 includes multiple power node connection ports 111-119. The each of the connection ports may be configured to support power conversion for a defined portion of the power node group of power nodes.

The condition model may provide characteristics of the different portions. For example, the condition model may provide a center value for expected power flow (such as a mean value, a median value, a selected value for ease of conversion in combination with other center values, or other value). For example, the diversity model may provide an expected range of power flows for the defined portion. In some cases, the defined portion may be defined based on power flow values. However, other characteristics may be used. For example, power node age, power node operating voltage, power node internal resistance (e.g., battery resistance or other internal resistance), power store charge-discharge cycle count, power node current, or other characteristics. In some cases, the populations may be statistically defined (e.g., a percentiles based on expected distributions due to power node age, cycle count, or other factors). Accordingly, membership of a particular power node within any particular portion of group may not be fully discernable. Hence, in some cases, the ports may be configured for different portions and then power nodes may be coupled to particular ports based on a best guess and/or best fit membership assignment. As an illustrative example, a particular PCD may have four ports tuned to different quartiles of total group of power nodes. At the time the PCD is placed into operation, power nodes may be partially characterized, for example, an operating voltage for each power node may be measured. Then, based on the partial characterization, the power nodes may be assigned based on a ranking of the characterized value. For example, in a best fit port assignment scheme the lowest operating voltage measured may be assumed to be best placed in the port of the lowest quartile (or other binning scheme), including in circumstances where the lowest measured operating voltage may be suggestive of membership in another quartile. In a best guess scheme, the measured characteristic may be used to estimate membership. For example, the lowest measured operating voltage may be assigned to the quartile indicated most strongly by the actual measured voltage value without consideration with regard to ranking in relationship to other power nodes characterized along with that power node at the time of its installation.

The PCD 100 further includes node interconnects 140 between the multiple power node connection ports 111-119. The node interconnects 140 may be configured to couple the power node connection portions 111-119 in a parallel or series configuration. In some cases, one or more series string of ports may be coupled in parallel to other individual ports. The PCD 100 further includes interconnects 130 between the multiple power node connection ports 111-119 and a sparse set of power converters 141, 142, 144. The sparse set works to adjust power at different points to ensure a final uniform model-corrected power at the port 150.

As discussed below, the interconnects may include dynamic switching to support reconfiguration of the connections over time. The switching may allow the power converter-power source connections to be changed after initial setup, for example, as a result of non-uniform degradation among the power sources. In some cases, dynamic reconfiguration may be applied in response to different use conditions. For example, the ports 111-119 may be switched such that they are coupled in series when power flows outward from the ports. For example, this may correspond to coupled batteries discharging during operation. However, the ports 111-119 may be switched such that they are couple in parallel when power flows inward to the ports. For example, this may correspond to coupled batteries charging.

The tier interconnects 130 may include a set of dense power converters 131-139 to provide a first stage adjustment (e.g., with partial power processing of the model-deviation power) the power node connection ports 111-119 in accord with the center values provided by the model. In some cases, such adjustment may include differential and/or partial conversion to an interim value that is selected in reference to the center values from the condition model, but differs from the referenced center values. For example, an interim value may include a value corresponding to multiple center values added together, a difference between two center values, or other target value referencing the center values. In some cases, the interim values may be the center values from the condition model. The model-deviation power may include the portion of the power that deviates from the center values provided by the condition model. The dense set of power converters 131-139 may be connected in one or more tiers (which are be below the sparse set 141, 142, 144 within the hierarchy). The total number of tiers in the power converter hierarchy may include the number of tiers of dense set power 131-139 converters added to the number of tiers of sparse set of power converters.

The tier interconnects 130 further include passive connections (e.g., parallel, series, capacitive, inductive, power converting, and/or other interconnects) to assist in the adjustment. Accordingly, the tier interconnects 130 may not necessarily connect the power node connection ports one-to-one with dense tier power converters. For example, multiple series connected nodes may be used to estimate a desired operating voltage before connection to a power converter. Accordingly, the power from multiple node connection ports may be processed by a single converter. In some cases, for simplicity of analysis and/or presentation a complex electrical system may be referred to, depicted as, or reduced (via circuit equivalents) to a single node and/or single node connection port. In various implementations, connection ports may be permanently wired to a particular power node. Accordingly, a port may include a power interface for power flow out of and/or into a power node regardless of the permanent or temporary nature of the coupling of the interface.

The interconnects 140 may be controlled by binning logic 200 which may control binning for the power nodes after a specific set of power nodes is selected to occupy the ports 111-119.

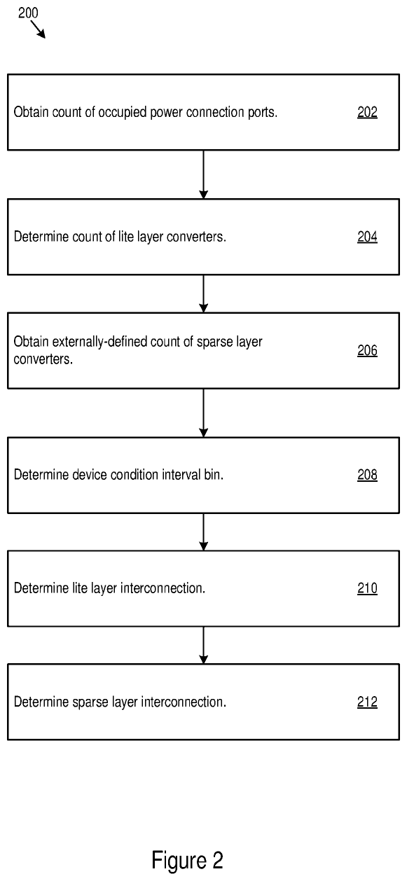

FIG. 2 shows example, binning logic 200. The binning logic 200 may obtain in indication of a count of occupied power connection ports (202). The count may indicate how many of the available ports are filled. In some cases, less than all ports may be coupled to power nodes due to availability, maintenance of an option to expand the system, and/or other factors. As discussed above, a power device condition model (such as a degradation model) characterizes the expected condition of a population power devices used to occupy the power connection ports. In some cases, the count may be user-defined. For example, a user may input a number of ports that are (or will be) occupied.

Based on the count of the occupied power connection ports, the binning logic may determine a count of lite layer converters based on a pre-defined constraint relating the count of occupied power connection ports to the count of lite layer converters. In various implementations, the lite layer converters may be active at a particular ratio to the occupied ports (204). For example, there may be one active lite layer converter for every two occupied ports, or one-to-one, or N-1 (where N is the count of ports), or other relationship. Thus, one or more of the lite layer converters may be deactivated by the binning logic if occupancy of the ports is less than full. In various implementations, the lite layer converters may be configured to process power from the occupied power connection ports with a remaining power mismatch in a range predicted via the power device condition model.

The binning logic 200 may obtain an externally-defined count of sparse layer converters (206). The sparse layer converter count may be set at the time of manufacture of the power processing system. The sparse layer converters are constrained to process the remaining power mismatch (e.g., predicted by the condition model) from the lite layer converters. The mismatch at the sparse layer may match the predicted mismatch from the model because the lite layer converters may provide correction such that the mismatch upon reaching the sparse layer matches that of the prediction (regardless of the mismatch prior to the lite layer correction).

Based on the counts, the binning logic may, for each of the occupied power connection ports, determine a device condition interval bin that characterizes a condition for that occupied power connection port. In various implementations, the number of bins may be based on the condition model and the number of ports available in the power processing system. For example, the bins may correspond to a discretization of condition model data. As an illustrative scenario, degradation data may exhibit modal clustering, the number of bins may be affected by the number of modes. In other instances, the number of bins may be affected by the number of available ports. For example, a system may have three ports available. Accordingly, three bins may correspond to a usable resolution level of the model by the power processing system.

Based on the counts and the bins, the binning logic 200 may determine a lite layer interconnection configuration (208). The lite layer interconnection configuration may determine the which logical port is connected to which power node. The binning logic 200 may then interconnect the sparse layer nodes by determining a sparse layer interconnection configuration (210) that adjusts to the number of occupied power ports and active lite layer converters.

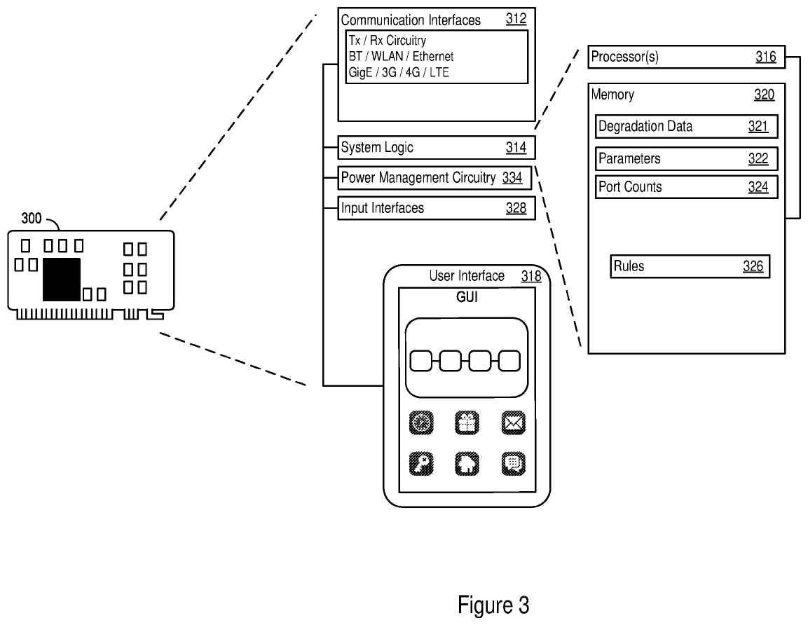

FIG. 3 shows an example binning execution system (BES) 300, which may provide an execution environment for execution of the binning logic 200. The BES 300 may include system logic 314 to support configuration simulation, Monte Carlo modelling; layer interconnection determination; and/or other operations. The system logic 314 may include processors 316, memory 320, and/or other circuitry, which may be used to implement the instructions and/or logic for interconnect determination.

The memory 320 may be used to store degradation data 322 and/or port counts 324 used or other data. The memory 320 may further store parameters 321, such as constraints, power converter ratings, and/or other parameters that may facilitate interconnect determination. The memory may further store rules 326, which may support interconnect determination.

The memory 320 may further include applications and structures, for example, coded objects, templates, or one or more other data structures to support interconnect determination. The BES 300 may also include one or more communication interfaces 312, which may support wireless, e.g. Bluetooth, Wi-Fi, WLAN, cellular (3G, 4G, LTE/A), and/or wired, ethernet, Gigabit ethernet, optical networking protocols. Additionally, or alternatively, the communication interface 312 may support secure information exchanges, such as secure socket layer (SSL) or public-key encryption-based protocols for sending and receiving data. The BES 300 may include power management circuitry 334 and one or more input interfaces 328.

The BES 300 may also include a user interface 318 that may include man-machine interfaces and/or graphical user interfaces (GUI). The GUI may be used to present prompts for user input of power converter counts, interconnect preferences, and/or other user input.

The methods, devices, processing, and logic described above may be implemented in many different ways and in many different combinations of hardware and software. For example, all or parts of the implementations may be circuitry that includes an instruction processor, such as a Central Processing Unit (CPU), microcontroller, or a microprocessor; an Application Specific Integrated Circuit (ASIC), Programmable Logic Device (PLD), or Field Programmable Gate Array (FPGA); or circuitry that includes discrete logic or other circuit components, including analog circuit components, digital circuit components or both; or any combination thereof. The circuitry may include discrete interconnected hardware components and/or may be combined on a single integrated circuit die, distributed among multiple integrated circuit dies, or implemented in a Multiple Chip Module (MCM) of multiple integrated circuit dies in a common package, as examples.

The circuitry may further include or access instructions for execution by the circuitry. The instructions may be embodied as a signal and/or data stream and/or may be stored in a tangible storage medium that is other than a transitory signal, such as a flash memory, a Random Access Memory (RAM), a Read Only Memory (ROM), an Erasable Programmable Read Only Memory (EPROM); or on a magnetic or optical disc, such as a Compact Disc Read Only Memory (CDROM), Hard Disk Drive (HDD), or other magnetic or optical disk; or in or on another machine-readable medium. A product, such as a computer program product, may particularly include a storage medium and instructions stored in or on the medium, and the instructions when executed by the circuitry in a device may cause the device to implement any of the processing described above or illustrated in the drawings.

The implementations may be distributed as circuitry, e.g., hardware, and/or a combination of hardware and software among multiple system components, such as among multiple processors and memories, optionally including multiple distributed processing systems. Parameters, databases, and other data structures may be separately stored and managed, may be incorporated into a single memory or database, may be logically and physically organized in many different ways, and may be implemented in many different ways, including as data structures such as linked lists, hash tables, arrays, records, objects, or implicit storage mechanisms. Programs may be parts (e.g., subroutines) of a single program, separate programs, distributed across several memories and processors, or implemented in many different ways, such as in a library, such as a shared library (e.g., a Dynamic Link Library (DLL)). The DLL, for example, may store instructions that perform any of the processing described above or illustrated in the drawings, when executed by the circuitry.

The present disclosure has been described with reference to specific examples that are intended to be illustrative only and not to be limiting of the disclosure. Changes, additions and/or deletions may be made to the examples without departing from the spirit and scope of the disclosure. Various implementations have been described and various implementations are possible. Table 1 includes various examples.

1. A system including:
a processor; and
memory in data communication with the processor, the memory including
instructions configured to cause the processor to:
obtain in indication of a count of occupied power connection ports, where a
power device condition model characterizes the expected condition of a
population power devices used to occupy the power connection ports;
determine based on the count of occupied power connection ports, a count
of lite layer converters based on a pre-defined constraint relating the count
of occupied power connection ports to the count of lite layer converters,
the lite layer converters configured to process power from the occupied
power connection ports to place a power mismatch in a range predicted
via the power device condition model;
obtain an externally-defined count of sparse layer converters, where the
sparse layer converters are constrained to process the power mismatch
not accounted for with the lite layer converters;
for each of the occupied power connection ports, determine a device
condition interval bin, from a pre-determined number of bins, that
characterizes a condition for that occupied power connection port;
based on the count of lite layer converters and the device condition interval
bins for the occupied power connection ports, determine a lite layer
interconnection configuration; and
based on the lite layer interconnection configuration and the externally-
defined count of sparse layer converters, determine a sparse layer
interconnection configuration.
2. The system, product, or method of any other example in this table, where
the externally-defined count includes a user-defined count.
3. The system, product, or method of any other example in this table, where:
the pre-determined number of bins includes three bins; and
the three bins cover three intervals of a degradation lifetime of a population of
power storage devices.
4. The system, product, or method of any other example in this table, where
the one or more occupied power connection ports are connected to one or more
batteries.
5. The system, product, or method of any other example in this table, where
the one or more occupied power connection ports are connected to one or more
power generation sources.
6. The system, product, or method of any other example in this table, where
the power device condition model is based on empirically collected data on
battery degradation for a defined battery population.
7. The system, product, or method of any other example in this table, where
the pre-determined number of bins includes bins discretized from data from the
power device condition model.
8. The system, product, or method of any other example in this table, where
the instructions are further configured to re-determine the device condition
interval bin for each of the occupied power connection ports after a monitoring
period in which condition trajectory information is obtained for the power ports.
9. The system, product, or method of any other example in this table, where
the monitoring period is a predetermined duration based on a portion of the
expected lifetime of a power node coupled to at least one of the occupied power
connection ports.
10. A method including:
obtaining in indication of a count of occupied power connection ports, where a
power device condition model characterizes the expected condition of a
population power devices used to occupy the power connection ports;
determining based on the count of occupied power connection ports, a count of lite
layer converters based on a pre-defined constraint relating the count of occupied
power connection ports to the count of lite layer converters, the lite layer
converters configured to process power from the occupied power connection
ports to place a power mismatch in a range predicted via the power device
condition model;
obtaining an externally-defined count of sparse layer converters, where the sparse
layer converters are constrained to process the power mismatch not accounted
for with the the lite layer converters;
for each of the occupied power connection ports, determining a device condition
interval bin, from a pre-determined number of bins, that characterizes a condition
for that occupied power connection port;
based on the count of lite layer converters and the device condition interval bins
for the occupied power connection ports, determining a lite layer interconnection
configuration; and
based on the lite layer interconnection configuration and the externally-defined
count of sparse layer converters, determining a sparse layer interconnection
configuration.
11. The system, product, or method of any other example in this table, where
the externally-defined count includes a user-defined count.
12. The system, product, or method of any other example in this table, where:
the pre-determined number of bins includes at least three bins; and
the at least three bins cover at least three intervals of a degradation lifetime of a
population of power storage devices.
13. The system, product, or method of any other example in this table, where
the one or more occupied power connection ports are connected to one or more
batteries.
14. The system, product, or method of any other example in this table, where
the one or more occupied power connection ports are connected to one or more
power generation sources.
15. The system, product, or method of any other example in this table, where
the power device condition model is based on empirically collected data on
battery degradation for a defined battery population.
16. The system, product, or method of any other example in this table, where
the pre-determined number of bins includes bins discretized from data from the
power device condition model.
17. A product including:
machine-readable media other than a transitory signal; and
instructions stored on the machine-readable media, the instructions configured to,
when executed, cause a processor to:
obtain in indication of a count of occupied power connection ports, where a
power device condition model characterizes the expected condition of a
population power devices used to occupy the power connection ports;
determine based on the count of occupied power connection ports, a count
of lite layer converters based on a pre-defined constraint relating the count
of occupied power connection ports to the count of lite layer converters,
the lite layer converters configured to process power from the occupied
power connection ports to place a power mismatch in a range predicted
via the power device condition model;
obtain an externally-defined count of sparse layer converters, where the
sparse layer converters are constrained to process the power mismatch
not accounted for with the lite layer converters;
for each of the occupied power connection ports, determine a device
condition interval bin, from a pre-determined number of bins, that
characterizes a condition for that occupied power connection port;
based on the count of lite layer converters and the device condition interval
bins for the occupied power connection ports, determine a lite layer
interconnection configuration; and
based on the lite layer interconnection configuration and the externally-
defined count of sparse layer converters, determine a sparse layer
interconnection configuration, where:
optionally, the product is in accord with any other example in this table.
18. The system, product, or method of any other example in this table, where
the power device condition model is based on empirically collected data on
battery degradation for a defined battery population.
19. The system, product, or method of any other example in this table, where
the instructions are further configured to cause the processor to re-determine the
device condition interval bin for each of the occupied power connection ports
after a monitoring period in which condition trajectory information is obtained for
the power ports.
20. The system, product, or method of any other example in this table, where
the monitoring period is a predetermined duration based on a portion of the
expected lifetime of a power node coupled to at least one of the occupied power
connection ports.

The foregoing description is given for clearness of understanding only, and no unnecessary limitations should be understood therefrom.

1. A system including:
a processor; and
memory in data communication with the processor, the memory including instructions configured to cause the processor to:
obtain an indication of a count of occupied power connection ports, where a power device condition model characterizes the expected condition of a population power devices used to occupy the power connection ports;
determine based on the count of occupied power connection ports, a count of lite layer converters based on a pre-defined constraint relating the count of occupied power connection ports to the count of lite layer converters, the lite layer converters configured to process power from the occupied power connection ports to place a power mismatch in a range predicted via the power device condition model;
obtain an externally-defined count of sparse layer converters, where the sparse layer converters are constrained to process the power mismatch not accounted for the lite layer converters;
for each of the occupied power connection ports, determine a device condition interval bin, from a pre-determined number of bins, that characterizes a condition for that occupied power connection port;
based on the count of lite layer converters and the device condition interval bins for the occupied power connection ports, determine a lite layer interconnection configuration; and
based on the lite layer interconnection configuration and the externally-defined count of sparse layer converters, determine a sparse layer interconnection configuration.

2. The system of claim 1, where the externally-defined count includes a user-defined count.

3. The system of claim 1, where:
the pre-determined number of bins includes at least three bins; and
the at least three bins cover at least three intervals of a degradation lifetime of a population of power storage devices.

4. The system of claim 1, where the one or more occupied power connection ports are connected to one or more batteries.

5. The system of claim 1, where the one or more occupied power connection ports are connected to one or more power generation sources.

6. The system of claim 1, where the power device condition model is based on empirically collected data on battery degradation for a defined battery population.

7. The system of claim 1, where the pre-determined number of bins includes bins discretized from data from the power device condition model.

8. The system of claim 1, where the instructions are further configured to re-determine the device condition interval bin for each of the occupied power connection ports after a monitoring period in which condition trajectory information is obtained for the power ports.

9. The system of claim 1, where the monitoring period is a predetermined duration based on a portion of the expected lifetime of a power node coupled to at least one of the occupied power connection ports.

10. A method including:
obtaining an indication of a count of occupied power connection ports, where a power device condition model characterizes the expected condition of a population power devices used to occupy the power connection ports;
determining based on the count of occupied power connection ports, a count of lite layer converters based on a pre-defined constraint relating the count of occupied power connection ports to the count of lite layer converters, the lite layer converters configured to process power from the occupied power connection ports to place a power mismatch in a range predicted via the power device condition model;
obtaining an externally-defined count of sparse layer converters, where the sparse layer converters are constrained to process the power mismatch not accounted for by the lite layer converters;
for each of the occupied power connection ports, determining a device condition interval bin, from a pre-determined number of bins, that characterizes a condition for that occupied power connection port;
based on the count of lite layer converters and the device condition interval bins for the occupied power connection ports, determining a lite layer interconnection configuration; and
based on the lite layer interconnection configuration and the externally-defined count of sparse layer converters, determining a sparse layer interconnection configuration.

11. The method of claim 10, where the externally-defined count includes a user-defined count.

12. The method of claim 10, where:
the pre-determined number of bins includes three bins; and
the three bins cover three intervals of a degradation lifetime of a population of power storage devices.

13. The method of claim 10, where the one or more occupied power connection ports are connected to one or more batteries.

14. The method of claim 10, where the one or more occupied power connection ports are connected to one or more power generation sources.

15. The method of claim 10, where the power device condition model is based on empirically collected data on battery degradation for a defined battery population.

16. The method of claim 10, where the pre-determined number of bins includes bins discretized from data from the power device condition model.

17. A product including:
machine-readable media other than a transitory signal; and
instructions stored on the machine-readable media, the instructions configured to, when executed, cause a processor to:
obtain an indication of a count of occupied power connection ports, where a power device condition model characterizes the expected condition of a population power devices used to occupy the power connection ports;
determine based on the count of occupied power connection ports, a count of lite layer converters based on a pre-defined constraint relating the count of occupied power connection ports to the count of lite layer converters, the lite layer converters configured to process power from the occupied power connection ports to place a power mismatch in a range predicted via the power device condition model;
obtain an externally-defined count of sparse layer converters, where the sparse layer converters are constrained to process the power mismatch not accounted for by the lite layer converters;
for each of the occupied power connection ports, determine a device condition interval bin, from a pre-determined number of bins, that characterizes a condition for that occupied power connection port;
based on the count of lite layer converters and the device condition interval bins for the occupied power connection ports, determine a lite layer interconnection configuration; and
based on the lite layer interconnection configuration and the externally-defined count of sparse layer converters, determine a sparse layer interconnection configuration.

18. The product of claim 17, where the power device condition model is based on empirically collected data on battery degradation for a defined battery population.

19. The product of claim 17, where the instructions are further configured to cause the processor to re-determine the device condition interval bin for each of the occupied power connection ports after a monitoring period in which condition trajectory information is obtained for the power ports.

20. The product of claim 19, where the monitoring period is a predetermined duration based on a portion of the expected lifetime of a power node coupled to at least one of the occupied power connection ports.
